(19) United States
(12) Patent Application Publication
(10) Pub. No.: US 2023/0402265 A1
(43) Pub. Date: Dec. 14, 2023

(54) PROCESS CHAMBER AND SEMICONDUCTOR PROCESS DEVICE

(71) Applicant: BEIJING NAURA MICROELECTRONICS EQUIPMENT CO., LTD., Beijing (CN)

(72) Inventors: Yancheng LU, Beijing (CN); Gang WEI, Beijing (CN); Xingfei MAO, Beijing (CN)

(21) Appl. No.: 18/253,423

(22) PCT Filed: Nov. 17, 2021
(86) PCT No.: PCT/CN2021/131205

§ 371 Date: May 18, 2023

(30) Foreign Application Priority Data
Nov. 19, 2020 (CN) 202011299759.6

(51) Int. Cl. H01J 37/32; H01L 21/683

(52) U.S. Cl. CPC H01J 37/32715; H01L 21/6833; H01J 2237/2007; H01J 2237/20207; H01J 2237/2005

(57) ABSTRACT

The present disclosure provides a process chamber and a semiconductor process apparatus. The process chamber is applied in the semiconductor process apparatus and includes a chamber body, a base, and a chuck assembly. The reaction chamber is formed in the chamber body. The base is located in the reaction chamber. The chuck assembly is connected to the base and configured to carry a wafer. The base includes a base body and a plurality of cantilevers. The plurality of cantilevers are arranged evenly along the circumference of the base body. Each cantilever is connected to the inner wall of the chamber body and the outer wall of the base body. The chamber body, the base body, and the cantilever have an integral structure and are made of a material having the electrical conductivity and the thermal conductivity.

### TECHNICAL FIELD

The present disclosure generally relates to the semiconductor processing technology field and, more particularly, to a process chamber and a semiconductor process apparatus.

### BACKGROUND

Currently, a plasma process apparatus is widely used nowadays in a manufacturing process of a semiconductor, a solar cell, and a tablet display. In the current manufacturing process, a discharging type that uses the plasma process apparatus includes a capacitively coupled plasma (CCP) type, an inductively coupled plasma (ICP) type, and an electron cyclotron resonance plasma (ECR) type. Currently, these discharging types are widely used in a semiconductor process apparatus of physical vapor deposition (PVD), plasma etching and chemical vapor deposition (CVD), and plasma immersion ion implantation (PILI). To ensure good uniformity of an etching result from a center to an edge of a wafer, a process environment requires the process chamber radio frequency (RF) circuit of the semiconductor process apparatus to have good uniformity and also requires the process chamber temperature to have good uniformity.

However, in the existing technology, a base is mounted in the process chamber through a cantilever. Due to factors such as processing tolerances and assembly tolerances, a small gap exists between the cantilever and the chamber wall of the process chamber, which causes electrical conductivity and thermal conductivity between the cantilever and the chamber wall to be poor and results in lower wafer yield.

### SUMMARY

For the shortcomings of the existing methods, the present disclosure provides a process chamber and semiconductor process apparatus, which are configured to solve the problem of poor electrical conductivity and thermal conductivity between the base and the process chamber to cause low yield of the wafer in the existing technology.

In a first aspect, embodiments of the present disclosure provide a process chamber applied to a semiconductor process apparatus and including a chamber body, a base, and a chuck assembly. A reaction chamber is formed in the chamber body, the base is located in the reaction chamber, and the chuck assembly is connected to the base and configured to carry a wafer.

The base includes a base body and a plurality of cantilevers, the plurality of cantilevers are evenly arranged along a circumference of the base body at intervals. Each of the plurality of cantilevers is respectively connected to an inner wall of the chamber body and an outer wall of the base body.

The chamber body, the base body, and the cantilever can be formed integrally and made of a material having electrical conductivity and thermal conductivity.

In an embodiment of the present disclosure, the base body includes an accommodation chamber. The accommodation chamber includes an opening facing upward. Mounting channels communicating with the accommodation chamber are arranged in the plurality of cantilevers. Through-holes are arranged on the chamber body. The through-holes communicate the mounting channels to the outer side of the chamber body.

The chuck assembly is sealedly connected to the base body and configured to seal the opening of the accommodation chamber.

In an embodiment of the present disclosure, the mounting channels have openings facing upward on the cantilevers. The openings are communicated with the accommodation chamber.

The chuck assembly is further sealedly connected to the plurality of cantilevers and configured to seal the openings of the mounting channels.

In an embodiment of the present disclosure, the chuck assembly includes an interface plate. The interface plate includes a plate body and a plurality of cover plates connected to the interface plate. The plate body is sealedly connected to the base body and configured to seal the opening of the accommodation chamber.

A number of the cover plates is same as a number of the cantilevers. The plurality of cover plates are evenly distributed around the plate body at intervals. The cover plates are sealedly connected to the cantilevers in a one-to-one correspondence and configured to seal the openings of the mounting channels.

In an embodiment of the present disclosure, a positioning structure is arranged between each cover plate of the cover plates and the cantilever corresponding to the cover plate and configured to limit a position of the cover plate on the cantilever.

In an embodiment of the present disclosure, each positioning structure includes at least a pair of a positioning concave member and a positioning convex member. The positioning concave member is arranged on one of two surfaces of the cover plate and the cantilever. The positioning convex member is arranged on the other one of the two surfaces of the cover plate and the cantilever.

In an embodiment of the present disclosure, The base body includes a sidewall and a bottom cover. The bottom cover is detachably arranged at a bottom of the sidewall. An upper surface of the bottom cover and an inner surface of the sidewall enclose to form the accommodation chamber.

A maintenance opening is arranged at a position on the chamber body corresponding to the bottom cover, and the maintenance opening is communicated with the reaction chamber.

In an embodiment of the present disclosure, a diameter of an outer wall of the bottom cover gradually decreases in a vertical direction away from the sidewall.

In an embodiment of the present disclosure, two connection flanges are correspondingly arranged on the sidewall and the outer surface of the bottom cover. The two connection flanges are stacked with each other in a vertical direction and fixedly connected by a plurality of fasteners.

In a second aspect, embodiments of the present disclosure provide a semiconductor process apparatus, including a process chamber, a radio frequency (RF) assembly, an air inlet assembly, and an air outlet assembly. The process chamber adopts the process chamber provided in the first aspect. The RF assembly and the air inlet assembly are arranged on a top of the chamber body. The air outlet assembly is arranged at a bottom of the chamber body.

The present disclosure includes the following beneficial effects.

The beneficial technical effects brought by the technical solutions provided in embodiments of the present disclosure are as follows.

In the process chamber of embodiments of the present disclosure, the chamber body, the base body, and the cantilever are formed integrally and made of the same material with electrical conductivity and thermal conductivity. Thus, no gap exists between the cantilever and the chamber body, and the electrical conductivity between the cantilevers and the chamber body can be good, which greatly improves the uniformity of the RF circuit of the process chamber. In addition, the thermal conductivity from the chamber body to the cantilevers can be improved, and the uniformity of the overall temperature of the process chamber can be greatly improved. Thus, the yield of the wafer can be greatly improved. Further, since the chamber body, the base body, and the cantilever are formed integrally, which improves the structural stability of embodiments of the present disclosure and greatly reduces the application cost and the maintenance cost.

In the semiconductor process apparatus of embodiments of the present disclosure, by using the above process chamber of embodiments of the present disclosure, the uniformity of the RF circuit and the uniformity of the overall temperature of the process chamber can be greatly improved. Thus, the yield of the wafer can be greatly improved. In addition, the structural stability of embodiments of the present disclosure can be improved, and the application cost and the maintenance cost can be greatly reduced.

Additional aspects and advantages of the present disclosure are described below, which become apparent in the following description or may be known through practicing of the present disclosure.

### BRIEF DESCRIPTION OF THE DRAWINGS

The above and/or additional aspects and advantages of the present disclosure become apparent and easy to understand from the following description of embodiments in connection with the accompanying drawings

FIG. 1 illustrates a schematic perspective structural diagram of a process chamber ignoring a chuck assembly according to an embodiment of the present disclosure.

FIG. 2 illustrates a schematic perspective structural diagram of a chuck assembly according to an embodiment of the present disclosure.

FIG. 3 illustrates a schematic cross-section diagram of a process chamber according to an embodiment of the present disclosure.

FIG. 4 illustrates a schematic top view of a process chamber according to an embodiment of the present disclosure.

### DETAILED DESCRIPTION OF THE EMBODIMENTS

The present disclosure is described in detail below, and examples of embodiments of the present disclosure are illustrated in the accompanying drawings. The same or similar reference numerals refer to the same or similar components or components having the same or similar functions. In addition, detailed descriptions of known technologies can be omitted if the detailed descriptions are not necessary for illustrating features of the present disclosure. The embodiments described below with reference to the accompanying drawings are exemplary and are only used to explain the present disclosure, but are not to be understood as a limitation for the present disclosure.

Those skilled in the art can understand that, unless otherwise defined, all terms (including technical and scientific terms) used here have the same meaning as commonly understood by those of ordinary skill in the art to which the present disclosure belongs. It should also be understood that terms, such as those defined in a general dictionary, should be understood to have meanings consistent with meanings in the context of the existing technology. Unless specifically defined here, the terms should not be interpreted with idealistic or overly formal meaning.

The technical solutions of the present disclosure and how the technical solutions of the present disclosure solve the above technical problems are described in detail below with specific examples.

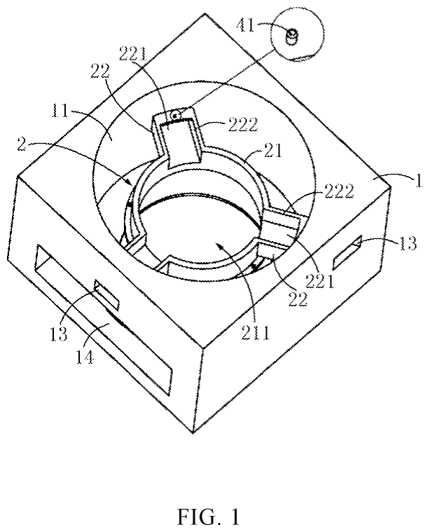

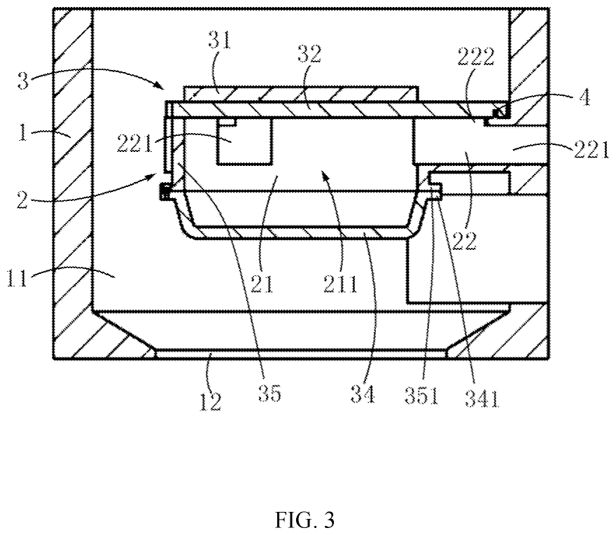

Embodiments of the present disclosure provide a process chamber, which can be applied to a semiconductor process apparatus. Schematic structural diagrams of the process chamber are shown in FIG. 1 and FIG. 3. The process chamber includes a chamber body 1, a base 2, and a chuck assembly 3. A reaction chamber 11 is formed in the chamber body 1. The base 2 is arranged in the reaction chamber 11. The chuck assembly 3 is connected to the base 2 and configured to carry a wafer (not shown in the figure). The base 2 includes a base body 21 and a plurality of cantilevers 22. The plurality of cantilevers 22 are evenly arranged along a circumference of the base body 21 at intervals. Each cantilever 22 is respectively connected to an inner wall of the reaction chamber 11 and an outer wall of the base body 21. The chamber body 1, the base body 21, and the cantilever 22 can be integrally formed and made of a material with electrical conductivity and thermal conductivity.

As shown in FIG. 1 and FIG. 3, the chamber body 1 is specifically a cubic structure made of a metal material. The hollow reaction chamber 11 is formed in the middle of the chamber body 1 and configured to accommodate the base 2 and the chuck assembly 3. In practical applications, a cover (not shown in the figure) can be arranged at a top of the chamber body 1. An air extraction port 12 at the bottom can be connected to an exhaust assembly (not shown in the figure) of the semiconductor process apparatus. The exhaust assembly can be configured to extract the air in the reaction chamber 11 to cause the reaction chamber 11 to be in a vacuum state to provide a reaction environment for the wafer.

The base 2 and the chamber body 1 can have an integral structure. The base 2 and the chamber body 1 can be made of a same material. The material can have the electrical conductivity and thermal conductivity, such as a metal material. Specifically, the base body 21 can have a cylindrical structure. Three cantilevers 22 can be arranged on an outer periphery of the base body 21. The three cantilevers 22 can be evenly distributed along the circumference of the base body 21 at intervals. The three cantilevers 22, the base body 21, and the chamber body 1 can be formed integrally. Two ends of each cantilever 22 can be connected to the inner wall of the chamber body 1 and the outer wall of the base body 21, respectively. An overall structure of the chuck assembly 3 can have a disc-shaped structure. The chuck assembly 3 can be arranged at the top of the base body 21 and configured to carry and absorb the wafer.

In the process chamber of embodiments of the present disclosure, the chamber body, the base body, and the cantilevers can be formed integrally with the same material with the electrical conductivity and thermal conductivity. Thus, no gap can exist between the cantilevers and the chamber body, and the electrical conductivity between the cantilevers and the chamber body can be good, which greatly improves the uniformity of the RF circuit of the process chamber. In addition, the thermal conductivity from the chamber body to the cantilevers can be improved. Therefore, the uniformity of the overall temperature of the process chamber can be greatly improved to greatly improve the yield of the wafer. Further, since the chamber body, the base body, and the cantilevers have an integral structure, the stability of the structure of the present disclosure can be improved, and the application and maintenance costs can be greatly reduced.

It should be noted that the specific implementation of the cantilever 22 and the chamber body 1 are not limited in embodiments of the present disclosure. For example, two or more than three cantilevers 22 can be included, and the chamber body 1 can also have a cylindrical structure. Therefore, embodiments of the present disclosure are not limited here, and those skilled in the art can adjust the settings by themselves according to the actual situation.

In an embodiment of the present disclosure, as shown in FIG. 1, the base body 21 includes an accommodation chamber 211. The accommodation chamber 211 includes an opening facing upward. Each of the plurality of cantilevers 22 includes a mounting channel 221 communicating with the accommodation chamber 211. A through-hole 13 is formed on the chamber body 1. The through-hole 13 can be configured to communicate the mounting channel 221 to an outer side of the chamber body 1. The chuck assembly 3 can be sealedly connected to the base body 21 and configured to seal the opening of the accommodation chamber 211.

As shown in FIG. 1, the base body 21 has specifically a cylindrical structure to form the accommodation chamber 211 in the base body 21. Each cantilever 22 has, for example, a rectangular rod-shaped structure. The cantilever 22 has a hollow structure to form the mounting channel 221. The chamber body 1 includes the through hole 13 corresponding to the mounting channel 221 in each cantilever 22. Specifically, the through-hole 13 can have a rectangular structure, and a cross-sectional dimension of the through-hole 13 can be the same as the dimension of the mounting channel 221 in the cantilever 22. The mounting channel 221 can be configured to arrange components (not shown in the figure) such as cables, air pipes, and water pipes connected inside and outside the chamber body 1 and components with suitable sizes. Thus, occupation of the outer space of the chamber body 1 and the space of the chamber body 1 can be greatly saved.

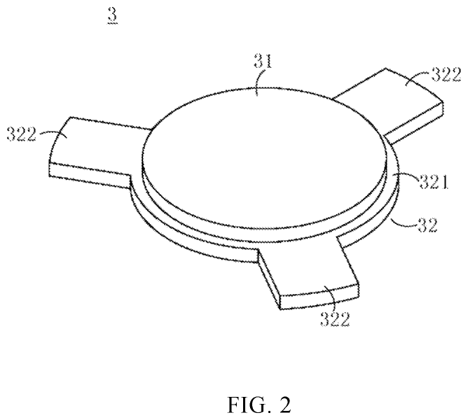

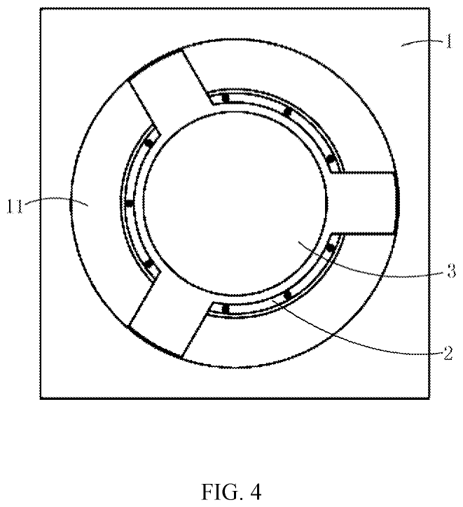

In an embodiment of the present disclosure, as shown in FIG. 1 to FIG. 4, the mounting channel 221 includes an opening 222 facing upward on the cantilever 22. The opening 222 communicates with the accommodation chamber 211. The chuck assembly 3 can also be sealed with and connected to the plurality of cantilevers 22 and configured to seal the opening 222 of the mounting channel 221.

In an embodiment of the present disclosure, the chuck assembly 3 includes an interface plate 32, and the interface plate 32 is sealedly arranged over the above opening of the accommodating cavity 211.

Specifically, the interface plate 32 of the chuck assembly 3 can be a disk-shaped structure made of a metal material. The interface plate 32 can be arranged on the top of the base body 21 to seal the opening of the accommodation chamber 211. The interface plate 32 can be detachably connected to the base body 21 to improve the assembly and maintenance efficiency of embodiments of the present disclosure. In addition, since the base body 21 and the cantilever 22 have a hollow structure, the manufacturing cost of embodiments of the present disclosure can also be greatly reduced.

It should be noted that the specific shape of the cantilever 22 is not limited in embodiments of the present disclosure. For example, the cantilever 22 can also have a round rod-shaped structure. Therefore, embodiments of the present disclosure are not limited here, and those skilled in the art can adjust the settings by themselves according to the actual situation.

In an embodiment of the present disclosure, as shown in FIG. 1 to FIG. 4, the interface plate 32 includes a plate body 321 and a plurality of cover plates 322 connected to the plate body 321. The plate body 321 can be sealed with and connected to the base body 21 and configured to seal the opening of the accommodation chamber 211. A number of cover plates 322 can be same as a number of cantilevers 22. The plurality of cover plates 322 can be distributed evenly around the plate body 321 at intervals. The cover plates 322 can be sealedly connected to the cantilevers 22 in a one-to-one correspondence and configured to seal the opening 222 of the mounting channel 221.

In an embodiment of the present disclosure, the plate body 321 and the plurality of cover plates 322 can be integrally formed.

When the interface plate 32 is mounted at the base body 21, three cover plates 322 can be correspondingly covered on the three cantilevers 22 and configured to seal the openings 222 of the mounting channels 221 of the three cantilevers 22 in a one-to-one correspondence to protect the components mounted in the mounting channels 221 of the cantilevers 22, which prevents the components from being corroded when performing the process in the process chamber to further greatly reduce the failure rate and improve the service life. In practical application, by dissembling the interface plate 32, the maintenance can be performed on the components in the base body 21 and the cantilever 22 through the opening 222. Thus, the assembly and maintenance efficiency of embodiments of the present disclosure can be greatly improved.

It should be noted that a number of cover plates 322 are not limited in embodiments of the present disclosure, as long as the number of the cover plates 322 is set corresponding to the number of the cantilevers 22. Therefore, embodiments of the present disclosure are not limited here, and those skilled in the art can adjust the setting by themselves according to the actual situation.

In an embodiment of the present disclosure, as shown in FIG. 1 to FIG. 4, the chuck assembly 3 includes an electrostatic chuck 31. The electrostatic chuck 31 is arranged on the plate body 321 and configured to carry a wafer.

As shown in FIG. 1 to FIG. 4, the electrostatic chuck 31 specifically has a disc-shaped structure made of a ceramic material. A top surface of the electrostatic chuck 31 can be configured to carry a wafer. A bottom surface of the electrostatic chuck 31 can be attached to the plate body 321. The plate body 321 can be covered on the top of the base body 21. The plate body 321 can be configured to mount the electrostatic chuck 31 and provide an interface for an electrode and a back air of the electrostatic chuck 31. A diameter of the plate body 321 can be larger than a diameter of the electrostatic chuck 31 to facilitate connection to the electrostatic chuck 31 and the base body 21. The connection can include a detachable connection to improve the assembly and maintenance efficiency of embodiments of the present disclosure. However, it should be noted that the specific type of the chuck assembly 3 is not limited in embodiments of the present disclosure, and those skilled in the art can adjust the setting according to the actual situation.

In an embodiment of the present disclosure, as shown in FIG. 1 to FIG. 3, a positioning structure 4 is arranged between each cover plate 322 and the cantilever 22 corresponding to the cover plate 322 to limit the position of the cover plate 322 on the cantilever 22. The positioning structure can have various structures. For example, each positioning structure 4 can include at least a pair of a positioning concave member and a positioning convex member that mutually cooperate with each other. The positioning concave member can be arranged on one of two surfaces of the cover plate 322 and the cantilever 22 opposite to each other. The positioning convex member can be arranged on the other one of the two surfaces of the cover plate 322 and the cantilever 22 opposite to each other. Specifically, as shown in FIG. 1, the positioning convex member is, for example, a positioning column 41 arranged on the top surface of the cantilever 22, and the positioning concave member is, for example, a positioning hole (not shown in the figure) arranged on the bottom surface of the cover plate 322. The positioning hole can cooperate with the positioning column 41 to define the position of the cover plate 322 on the cantilever 22.

As shown in FIG. 1 to FIG. 3, two pairs of positioning concave members and positioning convex members are included and located between two cantilevers 22 and two plate covers 322. The positioning structure 4 can be configured to position and mount the interface plate 32 at a correct position. However, embodiments of the present disclosure are not limited to this. For example, the positioning structure 4 can adopt a cooperation manner of a convex block and a concave groove. Those skilled in the art can adjust the setting according to the actual situation.

In an embodiment of the present disclosure, the outer peripheral surfaces of the three cover plates 322 can have a curved surface structure, and a diameter of the curved surface structure can be smaller than an inner diameter of the reaction chamber 11. A difference between the diameter of the curved surface structure and the inner diameter of the reaction chamber 11 can be, for example, around 2 mm. Thus, mechanical interference with the inner wall of the reaction chamber 11 can be avoided when the interface plate 32 is mounted. Therefore, the assembly and maintenance efficiency of embodiments of the present disclosure can be greatly improved, and the failure rate of embodiments of the present disclosure can be effectively reduced.

In addition, to facilitate the installation and sealing between the interface plate 32 and the base body 21, the seal structure can be on the top surface of the cantilever 22 close to the side wall of the reaction chamber 11. That is, a preset distance can be between a side of the opening 222 away from the accommodation chamber 211 and the side wall of the reaction chamber 11. The preset distance can be specifically 30 mm. A wall thickness of the cantilever 22 can be set to about 20 mm. The positioning column 41 can be arranged near the side wall of the reaction chamber 11 and configured to position the position of the interface plate 32. However, embodiments of the present disclosure are not limited to the above, and those skilled in the art can adjust the setting by themselves according to the actual situation.

In an embodiment of the present disclosure, as shown in FIG. 1 to FIG. 4, the base body 21 includes a side wall 35 and a bottom cover 34. The bottom cover 34 can be detachably arranged at the bottom of the side wall 35. The upper surface of the bottom cover 34 and the inner surface of the sidewall 35 can enclose to form an accommodation chamber 211. A maintenance opening 14 is arranged at a position on the chamber body 1 corresponding to the bottom cover 34. The maintenance opening 14 can be communicated with the reaction chamber 11 and configured to maintain the bottom cover 34.

As shown in FIG. 1 to FIG. 4, the bottom cover 34 has specifically a shell-shaped structure made of a metal material. The top surface of the bottom cover 34 can be connected to the bottom surface of the sidewall 35. The upper surface of the bottom cover 34 and the inner surface of the sidewall 35 can enclose to form the accommodation chamber 211. The bottom cover 34 can be configured to seal the accommodation chamber 211. Various components can be mounted in the accommodation chamber 211, for example, an ascending and descending assembly (not shown in the figure). The ascending and descending assembly can pass through the interface plate 32 and the electrostatic chuck 31 and can be configured to drive the wafer to ascend and descend relative to the chuck assembly 3. By dissembling the bottom cover 34, the components in the accommodation chamber 211 can be easily maintained. The bottom cover 34 and the sidewall 35 can cooperate and be connected through a flange and screws. Specifically, two connection flanges (351, 341) can be correspondingly arranged on the sidewall 35 and the outer surface of the bottom cover 34. The two flanges (341, 351) can be stacked with each other in the vertical direction and fixedly connected through a plurality of fasteners (not shown in the figure). However, embodiments of the present disclosure are not limited to this. For example, the bottom cover 34 and the sidewall 34 can be connected by a screw connection or snap connection. The bottom cover 34 can be detachably connected to the sidewall 35, which facilitates the maintenance of the ascending and descending assembly to greatly improve the assembly and maintenance efficiency.

It should be noted that not all embodiments of the present disclosure necessarily include the bottom cover 34. For example, the bottom cover 34 and the sidewall 35 can be formed integrally. A maintenance gate structure configured to maintain the components can be arranged on the sidewall 35. Thus, embodiments of the present disclosure are not limited to this. Those skilled in the art can adjust the height setting by themselves according to the actual situation. A rectangular maintenance opening 14 can be formed on the side surface of the chamber body 1. The length of the maintenance opening 14 can be greater than the diameter of the bottom cover 34. The height of the maintenance opening 14 can be greater than a thickness of the bottom cover 34 to facilitate the assembly and maintenance of the bottom cover 34. Thus, the assembly and maintenance efficiency of embodiments of the present disclosure can be greatly improved.

It should be noted that the specific position and shape of the maintenance opening 14 are not limited in embodiments of the present disclosure, as long as the maintenance opening 14 is arranged at a position corresponding to the position of the bottom cover 34. Thus, embodiments of the present disclosure are not limited to this. Those skilled in the art can adjust the setting by themselves according to the actual situation.

In an embodiment of the present disclosure, as shown in FIG. 3, the diameter of the outer wall of the bottom cover 34 gradually decreases along the vertical direction away from the side wall 35. Specifically, the bottom cover 34 can have a conical structure with a large upper and a small lower. That is, the outer diameter of the bottom cover 34 gradually decreases in the direction from a top surface to a bottom surface. With the above design, the bottom cover 34 can have a conical designed, which facilitates the gas in the chamber body 1 to flow to the lower air extraction port 12. Thus, the stability of the airflow in the reaction chamber 11 can be improved, and the yield of the wafer can be improved.

In an embodiment of the present disclosure, as shown in FIG. 1, the base 2 and the chamber body 1 are made of aluminum alloy. Specifically, the chamber body 1, the base body 21, and the cantilever 22 can be made of an aluminum alloy material. With an integral formation structure, the chamber body 1, the base body 21, and the cantilever 22 can have good electrical conductivity. Since the plurality of cantilevers 22 almost do not have any difference, the equivalent current of the RF circuit can flow to the chamber body 1 evenly through the circumference from the three cantilevers and can be grounded. Thus, the uniformity of the RF circuit can be improved. Specifically, the number of the cantilevers 22 can be three. The three cantilevers 22 can be evenly distributed at the outer periphery of the base body 21. An included angle between two neighboring cantilevers 22 can be 120°. With the good thermal conductivity among the chamber body 1, the base body 21, and the cantilever 22, the heat of the chamber body 1 can be transferred to the base body 21 through the three evenly distributed cantilevers 22. Thus, the temperature difference between the chamber body 1 and the base body 21 can be reduced, and the uniformity of the temperature at the base body 21 can be improved. The upper widths of the cross-sections of the cantilevers 22 at the chamber body 1 can be 100 to 200 mm. Embodiments of the present are not limited to this. A specific width of the cantilever 22 can be set according to the number of the cantilevers 22 and the impact on the airflow state in the reaction chamber 11. Thus, the specific specification of the cantilever is not limited in embodiments of the present disclosure. Those skilled in the art can adjust the setting according to the actual situation.

Based on the same inventive concept, embodiments of the present disclosure provide a semiconductor process apparatus, including a process chamber, an RF assembly, an air inlet assembly, and an air outlet assembly. The process chamber can adopt the process chamber of the above embodiments. The RF assembly and the air inlet assembly can be arranged at the top of the chamber body. The air outlet assembly can be arranged at the bottom of the chamber body.

By applying embodiments of the present disclosure, at least the following beneficial effects can be achieved.

In the semiconductor process apparatus of embodiments of the present disclosure, by using the above process chamber of embodiments of the present disclosure, the uniformity of the RF circuit and the overall temperature uniformity of the process chamber can be greatly improved. Thus, the yield of the wafer can be greatly improved. In addition, the structural stability of embodiments of the present disclosure can be improved, and the application and maintenance costs can be greatly reduced.

It can be understood that the above embodiments are only exemplary embodiments used to illustrate the principle of the present disclosure. However, the present disclosure is not limited to this. For those skilled in the art, without departing from the spirit and essence of the present invention, various modifications and improvements can be made, and these modifications and improvements are also within the protection scope of the present disclosure.

In the description of the present disclosure, it should be understood that the orientation or positional relationship indicated by the terms “center,” “upper,” “lower,” “front,” “rear,” “left,” “right,” “vertical,” “horizontal,” “top,” “bottom,” “inner,” “outer,” etc., can be the orientation or positional relationship based on the accompanying drawings. The terms are merely used to facilitate the description of the present disclosure and simplify the description and do not indicate or imply that the devices or elements must have the specific orientation or must be constructed or operated in the specific orientation. Thus, the terms cannot be understood as a limitation of the present disclosure.

The terms “first” and “second” are only used for descriptive purposes, and should not be considered to indicate or imply relative importance or implicitly indicate the number of technical features indicated. Thus, a feature defined by “first” or “second” can expressly or implicitly include one or more of that feature. In the description of the present disclosure, unless otherwise specified, “a plurality of” means two or more.

In the description of the present disclosure, it should be noted that, unless otherwise expressly specified and limited, the terms “installed,” “connected,” and “coupled” should be understood in a broad sense, for example, it can be a fixed connection, a detachable connection, or an integral connection. The connection can be a direct connection or an indirect connection through an intermediate medium and can be an internal communication of two elements. For those of ordinary skill in the art, the specific meanings of the above terms in the present disclosure can be understood in a specific situation.

In the description of the present disclosure, specific features, structures, materials, or characteristics can be combined in any suitable manner in any one or more embodiments or examples.

The above are only some embodiments of the present disclosure. It should be noted that for those skilled in the art, without departing from the principles of the present disclosure, several improvements and modifications can also be made, and these improvements and modifications should be within the scope of the present disclosure.

1. A process chamber applied to a semiconductor process apparatus comprising:
a chamber body including a reaction chamber, the base is located in the reaction chamber, and the chuck assembly is connected to the base and configured to carry a wafer;
a base located in the reaction chamber and including a base body and a plurality of cantilevers, the plurality of cantilevers being evenly arranged along a circumference of the base body at intervals, each cantilever of the plurality of cantilevers being connected to an inner wall of the chamber body and an outer wall of the base body and the chamber body, the base body, and the cantilevers being formed integrally and made of a material having electrical conductivity and thermal conductivity; and
a chuck assembly connected to the base and configured to carry a wafer.

2. The process chamber according to claim 1, wherein:
the base body includes an accommodation chamber;
the accommodation chamber includes an opening facing upward;
a mounting channel communicating with the accommodation chamber is arranged in the cantilever;
a through-hole is arranged on the chamber body and communicates the mounting channel to an outer side of the chamber body; and
the chuck assembly is sealedly connected to the base body and configured to seal the opening of the accommodation chamber.

3. The process chamber according to claim 2, wherein:
the mounting channel includes an opening facing upward on the cantilever, and the opening being communicated with the accommodation chamber; and
the chuck assembly is further sealedly connected to the cantilever and configured to seal the opening of the mounting channel.

4. The process chamber of claim 3, wherein:
the chuck assembly includes an interface plate, including:
a plate body sealedly connected to the base body and configured to seal the opening of the accommodation chamber; and
a plurality of cover plates connected to the plate body; and
a number of the cover plates is same as a number of the cantilevers;
the plurality of cover plates are evenly distributed around the plate body at intervals; and
the cover plates are sealedly connected to the cantilevers in a one-to-one correspondence each cover plates of the cover plates is configured to seal the opening of the mounting channel.

5. The process chamber according to claim 4, wherein a positioning structure is arranged between each cover plate of the cover plates and the cantilever corresponding to the cover plate and configured to limit a position of the cover plate on the cantilever.

6. The process chamber according to claim 5, wherein the positioning structure includes:
a positioning concave member arranged on one of two surfaces of the cover plate and the cantilever; and
a positioning convex member arranged on the other one of the two surfaces of the cover plate and the cantilever.

7. The process chamber according to claim 2, wherein:
the base body includes:
a sidewall; and
a bottom cover detachably arranged at a bottom of the sidewall, an upper surface of the bottom cover and an inner surface of the sidewall enclosing to form the accommodation chamber; and
a maintenance opening is arranged at a position on the chamber body corresponding to the bottom cover and communicated with the reaction chamber.

8. The process chamber of claim 7, wherein a diameter of an outer wall of the bottom cover gradually decreases in a vertical direction away from the sidewall.

9. The process chamber according to claim 7, wherein:
two connection flanges are correspondingly arranged on the sidewall and the outer surface of the bottom cover, stacked with each other in a vertical direction and fixedly connected by a plurality of fasteners.

10. A semiconductor process apparatus, comprising:
a process chamber including:
a chamber body including a reaction chamber, the base is located in the reaction chamber, and the chuck assembly is connected to the base and configured to carry a wafer;
a base located in the reaction chamber and including a base body and a plurality of cantilevers, the plurality of cantilevers being evenly arranged along a circumference of the base body at intervals, each cantilever of the plurality of cantilevers being connected to an inner wall of the chamber body and an outer wall of the base body, and the chamber body, the base body, and the cantilevers being formed integrally and made of a material having electrical conductivity and thermal conductivity; and
a chuck assembly connected to the base and configured to carry a wafer;
a radio frequency (RF) assembly;
an air inlet assembly, the RF assembly and the air inlet assembly being arranged on a top of the chamber body; and
an air outlet assembly arranged at a bottom of the chamber body.

11. The semiconductor process apparatus according to claim 10, wherein:
the base body includes an accommodation chamber;
the accommodation chamber includes an opening facing upward;
a mounting channel communicated with the accommodation chamber is arranged in the cantilever;
a through-hole is arranged on the chamber body and communicates the mounting channel to an outer side of the chamber body; and
the chuck assembly is sealedly connected to the base body and configured to seal the opening of the accommodation chamber.

12. The semiconductor process apparatus according to claim 11, wherein:
the mounting channel includes an opening facing upward on the cantilever, and the opening being communicated with the accommodation chamber; and
the chuck assembly is further sealedly connected to the cantilever and configured to seal the opening of the mounting channel.

13. The semiconductor process apparatus of claim 12, wherein:
the chuck assembly includes an interface plate, including:
a plate body sealedly connected to the base body and configured to seal the opening of the accommodation chamber; and
a plurality of cover plates connected to the plate body; and
a number of the cover plates is same as a number of the cantilevers;
the plurality of cover plates are evenly distributed around the plate body at intervals; and
the cover plates are sealedly connected to the cantilevers in a one-to-one correspondence, each cover plates of the cover plates is configured to seal the opening of the mounting channel.

14. The semiconductor process apparatus according to claim 12, wherein a positioning structure is arranged between each cover plate of the cover plates and the cantilever corresponding to the cover plate and configured to limit a position of the cover plate on the cantilever.

15. The semiconductor process apparatus according to claim 14, wherein the positioning structure includes:
a positioning concave member arranged on one of two surfaces of the cover plate and the cantilever; and
a positioning convex member arranged on the other one of the two surfaces of the cover plate and the cantilever.

16. The semiconductor process apparatus according to claim 11, wherein:
the base body includes:
a sidewall; and
a bottom cover detachably arranged at a bottom of the sidewall, an upper surface of the bottom cover and an inner surface of the sidewall enclosing to form the accommodation chamber; and
a maintenance opening is arranged at a position on the chamber body corresponding to the bottom cover and communicated with the reaction chamber.

17. The process chamber of claim 16, wherein a diameter of an outer wall of the bottom cover gradually decreases in a vertical direction away from the sidewall.

18. The process chamber according to claim 16, wherein:
two connection flanges are correspondingly arranged on the sidewall and the outer surface of the bottom cover, stacked with each other in a vertical direction, and fixedly connected by a plurality of fasteners.
